(19) United States
(12) Patent Application Publication
(10) Pub. No.: US 2020/0043699 A1
(43) Pub. Date: Feb. 6, 2020

(54) METHOD AND DEVICE FOR PROCESSING A SURFACE OF A SUBSTRATE BY MEANS OF A PARTICLE BEAM

(71) Applicant: SCIA SYSTEMS GMBH, Chemnitz (DE)

(72) Inventors: Thoralf Dunger, Chemnitz (DE); Marcel Demmler, Wilkau-Haßlau (DE); Carsten Schulze, Chemnitz (DE); Thomas Tonert, Chemnitz (DE); Michael Zeuner, Chemnitz (DE); Matthias Nestler, Nossen (DE)

(73) Assignee: SCIA SYSTEMS GMBH, Chemnitz (DE)

(21) Appl. No.: 16/342,949

(22) PCT Filed: Oct. 17, 2017
(86) PCT No.: PCT/EP2017/076448

§ 371 Date: Apr. 17, 2019

(30) Foreign Application Priority Data
Oct. 18, 2016 (DE) 10 2016 119 791.2

(51) Int. Cl. H01J 37/305; C23C 14/22; H01J 37/34

(52) U.S. Cl. CPC H01J 37/3053; C23C 14/221; H01J 2237/30483; H01J 37/3467; H01J 2237/3174; H01J 37/3405

(57) ABSTRACT

This invention relates to a method and a device for processing a surface of a substrate by means of a particle beam. The method comprises the irradiation of the surface of the substrate, wherein, in a first area of the surface of the substrate, the surface of the substrate is processed with the particle beam, which strikes the surface of the substrate in an unpulsed manner; and wherein, in a second area of the surface of the substrate, the surface of the substrate is processed with the particle beam, which strikes the surface of the substrate in a pulsed manner.

The invention relates to a method and a device for processing a surface of a substrate by means of a particle beam.

In the industry, methods for the treatment of surfaces on a coated semiconductor or other component surfaces are used, for example, when the surface of a device has bumps and the surface deviates from a target, i.e. a target surface that has too much or too little material, for example.

An excess of material can be removed, for example, by means of ion beam etching. In site-selective ion beam etching, an ion beam is moved relative to a surface to be treated. The surface to be treated can be divided into several surface segments. When scanning, the ion beam always remains in a surface segment for a predetermined time.

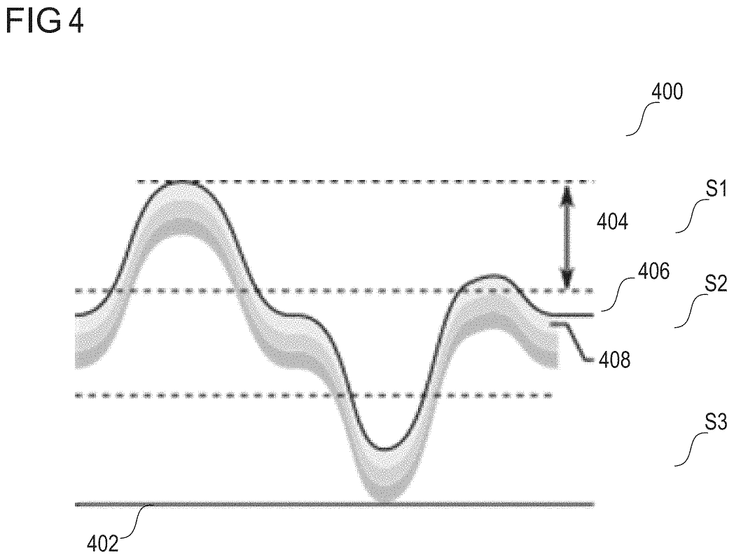

FIG. 4 shows a schematic cross-sectional view of a substrate 400 having a surface 406 that is to be processed to obtain a predetermined homogeneity and roughness 402 by means of an ion beam. In ion beam etching, material is removed from a surface 406 to be treated in each surface segment. The ion beam is passed multiple times, i.e. in several irradiation passes, so-called scans S1, S2, S3 across the surface and removes material with each scan.

At present, ion beams with a high temporal constancy of the current density distribution over the entire process duration are used for surface modification purposes in order to achieve a specified precise local substrate removal or substrate deposition.

During each scan, this may be a minimum amount of material, which is also referred to as a base etch 408. The base etch 406 depends on the beam profile of the ion beam, the energy of the ions, the technically maximum possible travel speed and the line feed. The amount of material removable per scan is limited to a maximum value 404 due to thermal stress on the substrate. During each scan, for example, a material layer having a thickness in a range of 5 nm to 30 nm can be removed by ion irradiation. To achieve larger removals, the substrate is therefore scanned several times.

However, the base etch results in an unnecessary removal of material over the entire surface of the component to be treated, which leads to unnecessary processing time and reduces the homogeneity in the target plane 402.

Alternatively, an electrically switched ion beam is used whose pulse duration is adapted to the respective surface segment. Those areas of the substrate for which a smaller change is intended are processed with less residence time and at the same time a shorter pulse duration of the ion beam, while those areas of the substrate for which a larger material removal is intended are processed with a correspondingly longer residence time and a longer pulse duration of the ion beam. The total residence time to be expended is divided equally between the number of scans S1, S2, S3.

Each pulse, however, results in a switching on and off of the ion beam on the surface segment. Due to the switching on and off process, the material removal has a temporal slope profile. The slope profile as well as the place where the switching process takes place may have temporal and/or spatial fluctuations. The slope profile causes a systematic error during the ion beam etching. As a result, each irradiation period has slope profiles from the switching on and off of the ion beam, so that the systematic errors of the individual periods add up. This reduces the precision of ion beam processing.

In various embodiments, a device and method for processing a surface of a substrate by means of a particle beam is provided, which mitigates or even avoids at least some of the above disadvantages.

A method for processing a surface of a substrate by means of a particle beam is provided in various embodiments. The method comprises irradiating the surface of the substrate with a particle beam. Upon irradiation, the surface of the substrate is processed with the particle beam in a first area of the surface of the substrate, which strike the surface of the substrate in an unpulsed manner. In at least a second area of the surface of the substrate, the surface of the substrate is processed upon irradiation with the particle beam, which strike the surface of the substrate in a pulsed manner.

The pulsed and unpulsed irradiation of the surface of the substrate can take place in a scanning process, i.e. a processing pass of the surface of the substrate.

By combining the unpulsed irradiation of the first pass with the pulsed irradiation of the second pass, the number of pulses required to process the surface can be reduced or minimized.

Accordingly, the error generated by the slopes of the pulses during the processing of the substrate can be reduced or minimized compared to a purely pulsed processing. Otherwise, the error of each pulse would add up over all radiation passes (scans). The error caused by the slopes of the pulses is generated, for example, by the steady particle beam profile when switching on and off the contact of the particle beam with the surface.

In comparison to an unpulsed surface processing, i.e. continuous wave processing, an unnecessary or inadequate processing of the surfaces can be avoided or reduced. As a result, the surface can be processed more precisely, and the surface can have a lower roughness or a higher homogeneity or conformity with a given surface quality.

In other different embodiments, the method comprises an irradiation of the surface of the substrate with the particle beam, with the surface of the substrate being processed with the particle beam when irradiating in a first area of the surface, the surface of the substrate is processed with the particle beam which, pulsed at a first duty cycle, strikes the surface of the substrate. In at least a second area of the surface of the substrate, the surface of the substrate is processed with the particle beam which, pulsed at a second duty cycle, strikes the surface of the substrate. The second duty cycle is different from the first duty cycle.

The duty cycle can also be referred to as a pulse duty factor, scanning rate or duty cycle. To determine the duty cycle, the surface can be subdivided into a plurality of equally sized segments or areas which are processed, i.e. irradiated, by means of the particle beam. For determining the duty cycle, it is further assumed that the segments are processed with the same or constant energy density of the particle beam per segment. The duty cycle thus results from the ratio of the time with a switched-on beam in the segment to the total residence time of the beam in the segment. The duty cycle thus relates in various embodiments to the residence time per area segment.

The size of a segment, i.e. its edge length, results for example from the beam profile of the particle beam, for example the half-width at a Gaussian beam and/or the step size, i.e. the minimal, mechanical change of the position of the particle beam on the surface of the substrate.

Clearly, the non-processing of the surface of the substrate has a duty factor of 0.0. The unpulsed processing has a duty cycle of 1.0. The pulsed processing has a duty cycle greater than 0.0 and smaller than 1.0.

For example, the first duty cycle may have a value ranging from 0.0 to 1.0. The second duty cycle has, for example, a value greater than 0.0 and smaller than 1.0.

In various embodiments, the method has an unpulsed irradiation in which the surface of the substrate is processed with the particle beam, which strikes the surface of the substrate in an unpulsed manner.

In various embodiments, a pulsed irradiation and an unpulsed irradiation may overlap in an area or segment of the surface. An unpulsed irradiation may also be referred to as continuous wave irradiation. The pulsed irradiation may, for example, have a lower removal or separation rate at constant energy density than the unpulsed irradiation. This facilitates a reduction of the pulse width and on/off operations of the particle beam (and associated with that fewer or smaller slopes of the particle beam control). This can result in a more reliable processing of the surface.

In various embodiments, however, the residence time per segment and the removal or separation rate between the individual segments can be varied, for example, to realize a pulse amplitude modulation or pulse frequency modulation. The residence time per area segment or per pulse is, for example, reduced or increased with respect to an unpulsed processing, for example at a constant energy density of the particle beam. As a result, the removal or separation rate can be varied and, clearly, the amplitude of the pulse can be increased or reduced. However, the removal or separation rate of the pulsed processing may be averaged over the respective area segment as well and correspond to the removal or separation rate of the unpulsed processing. By way of example, the pulsed processing may involve a processing of the surface of the substrate with relatively narrow pulses, i.e. a lower feed rate of the particle beam, with a high residence time. The feed rate is the advance of the particle beam within a scan line to control the residence time in the areas of the surface in the scan line. The line feed is the delivery of the particle beam from one scan line to the following scan line. The line feed cannot have any direct influence on the residence time of the particle beam in always one area of the surface.

In one embodiment, the pulsed irradiation of the surface takes place without or substantially without a pulse break and with increased or reduced pulse amplitude, for example based on an unpulsed irradiation of the same area of the surface, i.e. by means of a pulse amplitude modulation.

In one embodiment, the method further comprises the determination of a number of pulsed and unpulsed processes for each area of the surface to be processed. By clearly defining the processing of the substrate before the start of processing, an optimization of the processing of the surface is made possible.

In yet another embodiment, the determination of the number of pulsed processing operations may include the determination of pulse widths, pulse amplitudes, pulse shapes, pulse position and/or pulse distribution. For example, the duty cycle for the pulsed processing of the surface of the substrate with the particle beam results from the amount of material to be removed or separated. From this, the required number of pulses whose width, (slope) shape and position can be determined, for example, be optimized, so that a systematic error of the method is reduced.

The pulse distribution can, for example, have the position of pulses, for example with respect to one or more reference points. A reference point is, for example, the edge or the center of an area to be processed. A pulse distribution can, for example, be a mirror-symmetrical distribution of the pulses with respect to the center of an area to be processed.

In yet another embodiment, the particle beam may strike the surface of the substrate in a pulsed manner such that the pulses are arranged symmetrically with respect to the center of the area processed in a pulsed manner. This allows for a more homogeneous surface of the area processed in a pulsed manner.

In yet another embodiment, the method further comprises the definition of a base plane above or below a surface in at least one area of the substrate. The substrate is pulsed in the area when the surface of the area has a predetermined ratio to the base plane due to the processing.

The area can otherwise be processed in an unpulsed manner or not be processed by means of the particle beam.

In other words, the base plane may be defined above or below a surface in at least one area of the substrate. The substrate is pulsed in the area when the surface of the area has a predetermined ratio to the base plane and the area is otherwise processed in an unpulsed manner or not at all.

For example, the base plane is the plane at the center which is formed by means of a rough processing method, for example a chemical mechanical polishing. A pulsed, material-removing irradiation can be carried out, for example, in the event the surface of a segment of the surface is arranged below the base plane. An unpulsed, material-removing irradiation can be carried out, for example, in the event the surface of a segment of the surface is arranged above the base plane or in the vicinity of the base plane. The surface is located, for example, in the vicinity of the base plane when a predetermined target plane cannot yet be reached by means of an unpulsed irradiation.

Material is removed from the surface of the substrate in an unpulsed manner, for example, in an area of the substrate. If the surface in this area is in the base plane, the type of irradiation, i.e. the mode, can be changed for this area, for example, switched to a pulsed material removal. The material may, for example, be removed in a pulsed manner in this area, for example, until the surface of this area is arranged in a predetermined target plane. Subsequently, the processing of this area can be a non-irradiation, i.e. the particle beam can be blocked for subsequent scanning passes of the surface of the substrate in this area. In other words, at least one area of the surface of the substrate is processed in various embodiments in a pulsed and unpulsed manner. The pulsed processing and the unpulsed processing can be carried out simultaneously or at different times, for example in different scan passes. If the surface is located slightly above the base plane, a pulsed processing may, for example, have an overlapping of the pulsed and unpulsed processing. Thus, the number of scans can be reduced and/or the precision of the processing can be increased in various embodiments. The roughness or waviness of the surface of the substrate can be reduced after the processing, for example.

In yet another embodiment, the method further comprises the determination of the first duty cycle and the second duty cycle for each area of the surface to be processed.

In yet another embodiment, the pulsed irradiation takes place in an area of the surface after the unpulsed irradiation in the same area of the surface.

In yet another embodiment, the unpulsed irradiation of an area of the surface occurs after the pulsed irradiation of the same area of the surface.

In yet another embodiment, the pulsed and unpulsed irradiation takes place in an area of the surface after the non-pulsed irradiation of the entire surface of the substrate. Alternatively, the unpulsed irradiation of the entire surface of the substrate after the pulsed and unpulsed irradiation takes place in an area of the surface.

In various embodiments, the particle beam is a beam of neutral particles, an ion beam, a beam of particle bundles, a beam of neutral particle conglomerates (neutral particle clusters, so-called gas clusters), a beam of ionized particle conglomerates (so-called gas cluster ions), or an electron beam. Neutral particles are understood as outwardly uncharged particles, for example, atoms, molecules or conglomerates of one of the two. However, neutral particles may include, for example, partial charges or dipoles or the like. Ions or electrons are not neutral particles in this sense.

In various embodiments, when processing the surface with the particle beam, material may be removed from the surface or a portion of the surface of the substrate. The processing may, for example, be an ion beam etching.

Alternatively or additionally, when the surface is processed with the particle beam, material is deposited on the surface or part of the surface of the substrate. The processing is a magnetron sputtering, for example. In magnetron sputtering, an electric field and a magnetic field are superimposed in the radiation source so that the electrons of an excitation plasma are deflected onto a coiled path such as a helical line and circle over the surface of the sputtering material of the radiation source. This lengthens the path length of the electrons in the excitation gas and increases the number of collisions per charge carrier. The result is an intense low-pressure plasma, a so-called magnetron plasma. The positive charge carriers of this magnetron plasma are accelerated by an electrical potential on the surface of the sputtering material and release via impact processes neutral particles from this surface of the sputtering material. These triggered neutral particles in turn form a particle stream in the direction of the substrate, a neutral particle beam. In particular embodiments, the beam may also occur partially ionized.

In various embodiments, magnetron sputtering is high power impulse magnetron sputtering (HiPIMS).

For example, a pulser, i.e. a circuit breaker, is used for power regulation. Through pulsed discharges with powers greater than 1 MW, a higher degree of ionization of the particle beam can be achieved in the magnetron sputtering, which can, for example, lead to a change in the properties of a grown layer such as a higher adhesive strength of the grown layer.

In one embodiment, the first area may be different from the second area. The second area may be different in time and/or space. The second area is arranged for example next to the first area. Alternatively or additionally, the second area may be pulsed at a different time, i.e. a different irradiation, than the first area.

In one embodiment, the method further comprises detecting a surface condition of at least part of the surface of the substrate. The surface condition can be detected, for example, before irradiation. Based on the surface condition, a base plane, a target plane, the size of the segments of the surface as well as the duty cycles of the irradiation in the individual irradiation passes (scans) per segment can be determined.

By means of the multiple scans per surface segment, the heat introduced into the substrate can be reduced, since a portion of the heat is dissipated between the scans through heat dissipation and heat radiation. As a result, the thermal stress in the first area can be reduced, so that the substrate is exposed to a lower risk of breakage or that other adverse thermal influences on the substrate are avoided.

In yet another embodiment, the method further comprises the determination of a target plane above or below the surface of the substrate. The substrate is processed in at least one area of the surface of the substrate until it reaches the target plane.

In yet another embodiment, the method further comprises further irradiation of the surface of the substrate. During further irradiation, the particle beam is blocked in an area of the surface of the substrate in which, for example, the target plane has been reached, so that the surface in this area is not processed by the particle beam. The particle beam can be blocked, for example, by means of a shutter and/or switching off the particle beam.

In yet another embodiment, the method includes at least one other, further irradiation. The first area of the surface of the substrate of the unpulsed irradiation is processed during the other, further irradiation with the particle beam, which strikes the surface of the substrate in a pulsed manner. In other words, a previously unpulsed area can be pulsed at another time, for example during a later scan.

In various embodiments, a device for processing a surface of a substrate by means of a particle beam is provided. The device has a particle beam source which is designed to process the surface of the substrate with a particle beam. The device further includes a source controller for controlling the particle beam. The source controller is configured to irradiate the surface of the substrate with the particle beam, wherein in a first area of the surface of the substrate, the surface of the substrate is processed with the particle beam which impinges unpulsed on the surface of the substrate; and wherein, in a second area of the surface of the substrate, the surface of the substrate is processed with the particle beam pulsed on the surface of the substrate.

In various embodiments, a device for processing a surface of a substrate by means of a particle beam is provided. The device has a particle beam source which is designed to process the surface of the substrate with a particle beam. The device further includes a source controller for controlling the particle beam. The source controller is configured to irradiate the surface of the substrate with the particle beam, wherein, in a first area of the surface of the substrate, the surface of the substrate is processed with the pulsed particle beam striking the surface of the substrate in a first duty cycle; and wherein, in a second area of the surface of the substrate, the surface of the substrate is processed with the pulsed particle beam striking the surface of the substrate in a second duty cycle, the second duty cycle being different from the first duty cycle.

In one embodiment, the device has a process chamber. At least one part of the radiation source and the substrate are arranged in the process chamber, for example during the irradiation.

Embodiments of the invention are illustrated in the figures and are explained in more detail below.

The figures illustrate the following:

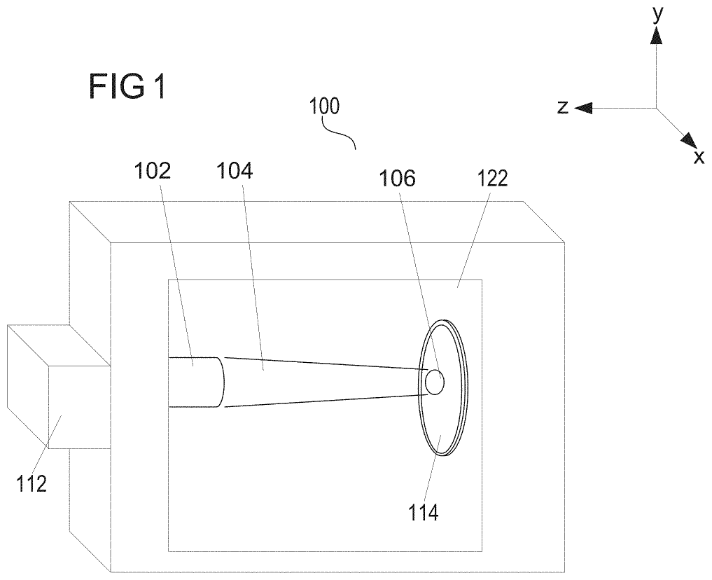

FIG. 1 a device according to various embodiments;

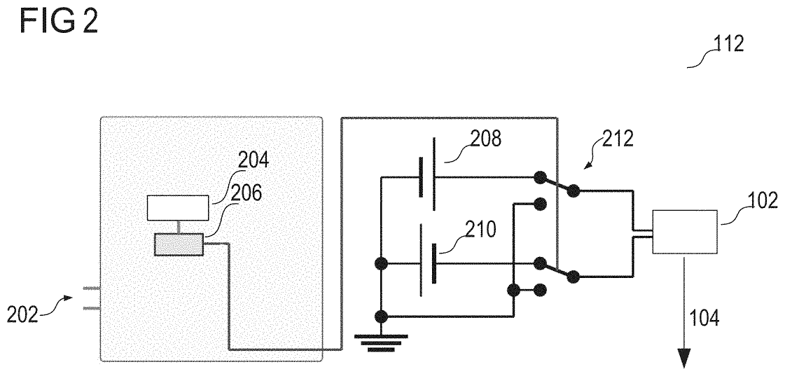

FIG. 2 a block diagram for the source control of a device according to various embodiments;

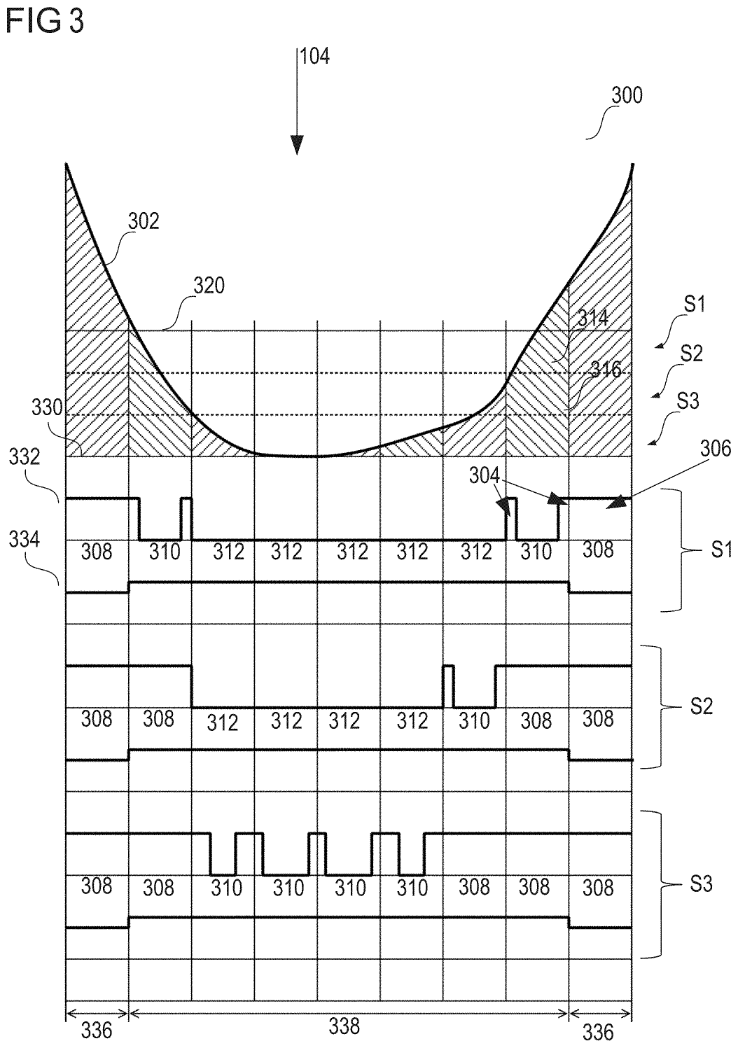

FIG. 3 a diagram of the method according to various exemplary embodiments; and

FIG. 4 a diagram for processing a surface of a substrate.

In the following detailed description, reference is made to the accompanying drawings, which form a part hereof, and in which specific embodiments in which the invention may be used are shown by way of illustration. In this regard, directional terminology such as “top”, “bottom”, “front”, “back”, “forward”, “backward”, etc. is used with reference to the orientation of the described figure(s). Since components of embodiments can be positioned in a number of different orientations, the directional terminology is illustrative and is in no way limiting. It should be understood that other embodiments may be utilized, and structural or logical changes may be made without departing from the scope of the present invention. It should be understood that the features of the various exemplary embodiments described herein may be combined with each other unless specifically stated otherwise. The following detailed description is therefore not to be taken in a limiting sense, and the scope of the present invention is defined by the appended claims.

As used herein, the terms “joined,” “connected,” and “coupled” are used to describe both a direct and an indirect joining, a direct or indirect connection, and a direct or indirect coupling. In the figures, identical or similar elements are provided with identical reference signs, as appropriate.

FIG. 1 shows a device 100 schematically. Such a device 100 is suitable, for example, for processing the surface of a substrate 114 by means of a particle beam 104.

The device 100 has a particle beam source 102, which is designed to emit a particle beam 104, which strikes an area of the surface of the substrate 114 in an area 106 (also called the strike area).

The particle beam source 102 is adapted to process the surface of the substrate with a particle beam, for example to remove material from the substrate or to separate material from the surface.

In one embodiment, the radiation source 102 is an ion beam source and the particle beam 104 is, for example, a focusing ion beam having a Gaussian charge current distribution density. The ion beam is used in this example to remove a thin layer from a substrate. The ion beam source may be configured as a broad-beam ion beam source.

The device 100 further includes a source controller 112 for controlling the particle beam 104. According to various embodiments, such a source controller 112 may change, control, pause, cancel and/or readjust the parameters and properties of the particle beam automatically or manually or with a corresponding combination. This may pertain, for example, to the position or the electrical operating currents for different components of the particle beam source 102. Likewise, this source controller 112 may pertain to direct or indirect parameters of the particle beam 104, such as the properties of a beam neutralizer, the composition and dose of source gases for the particle beam source, and/or temperatures of various components.

In addition, the source controller 112 may change the parameters of the particle beam source 102 and thus the particle beam 104. For example, an acceleration voltage can be changed, which has an effect on the kinetic energy of the charged particles in the particle beam. The source controller 112 may also include and control or regulate a gas supply (not shown) to or a plasma excitation (not shown) of the particle beam source 102 so that the number of particles in the particle beam 104 may be controlled. Gas delivery may be generally needed for particle beam sources to maintain a particle beam 104. Plasma excitation is generally required for particle beam sources that are operated with charged particles in order to produce the necessary charge carriers (e.g. ions) for a charged or non-neutral particle beam 104 from the gas that is supplied.

The source controller 112 is configured with the particle source 102 to irradiate the surface of the substrate 114, wherein, in a first area of the surface of the substrate 114, the surface of the substrate 114 is processed with the particle beam 104, which strikes the surface of the substrate 114 in an unpulsed manner, and wherein, in a second area of the surface of the substrate 114, the surface of the substrate 114 is processed with the particle beam 104, which strikes the surface of the substrate 114 in a pulsed manner.

Alternatively or additionally, the source control 112 for irradiation is arranged such that, in a first area of the surface of the substrate 114, the surface of the substrate 114 is processed with the particle beam 104, which, pulsed with a first duty cycle, strikes the surface of the substrate 114 and, in a second area of the surface of the substrate 114, the surface of the substrate 114 is processed with the particle beam 104, pulsed with a second duty cycle, strikes the surface of the substrate 114, the second duty cycle being different from the first duty cycle.

The source controller 112 is further provided with the particle source 102 for a non-pulsed irradiation of the surface of the substrate, wherein, in the non-pulsed irradiation, the surface of the substrate is processed with the particle beam 104 striking the surface of the substrate 114 in an unpulsed manner.

In one embodiment, the device 100 has a process chamber 122. At least one portion of the radiation source 102 and the substrate 114 are arranged in the process chamber 122, for example during irradiation. In other words: The device 100 has a process chamber 122 shown in a sectional view, in the interior of which a particle beam source 102 is arranged, which is configured to emit a particle beam 104.

The particle beam source 102 may be mounted in a wall of the process chamber 122 (movable or fixed) or within the process chamber 122 (for example at the bottom of a door of the process chamber 122, for example on a carriage on which the particle beam source 102 is mounted and along which the particle beam source 102 can be moved).

The process chamber 122 may further include a temperature controller that controls the temperature of the process chamber walls and adjacent devices. In various embodiments, a temperature controller may be useful, because the result of a processing of the substrate 114 with the particle beam 104 may be temperature-dependent. An electrical connection, for example to a grounding, may be useful in various embodiments to counteract an electrical charging of the substrate 114 during a processing with the particle beam.

The process chamber 122 may further comprise a beam neutralization device by means of which the charging of the substrate 114 during the processing with the particle beam can be counteracted. The substrate may be electrically connected to a reference potential, for example a grounding potential, to prevent charging.

The process chamber 122 may also include a suitable vacuum system with which the pressure within the process chamber 122 can be regulated, thus allowing a vacuum to be created inside the process chamber 122 as desired.

The position of the particle beam source 102 can be changed by means of a holder (not shown) and by means of the source control 112.

The holder may be configured to allow a translatory movement in one, in two or in all three spatial directions and/or a rotational movement around one, two or all three spatial axes. Alternatively or additionally, the substrate can be moved accordingly.

The particle beam 104 may strike a strike area 106 on the surface of the substrate. By means of the holder, the strike area 106 can be moved to any position or area on the surface of the substrate 114.

In one embodiment, a method for processing a substrate 114 may include the following:

A substrate 114 may be premeasured, i.e. the surface condition, for example, the surface unevenness, may be determined interferometrically. The surface unevenness information may be stored in a memory of a detector 122 (for example a processor such as a programmable processor and/or hardwired logic) as the initial state of the substrate 114.

The substrate 114 can then be held in the substrate holder and the process chamber 122 evacuated to a suitable process pressure by means of a vacuum system. The holder may be positioned such that the particle beam 104 strikes a shield, for example a diaphragm, when the particle beam source 102 is switched on.

Subsequently, the particle beam source 102 can be switched on by means of the source control 112. Depending on the embodiment, it is possible to wait until the particle beam source 102 has a stable particle beam 104, i.e., for example, until the particle beam 104 only has small intensity fluctuations.

The strike area 106 of the particle beam 104 can be changed by means of the source control 112 and the holder.

Depending on the desired application, it may be advantageous for the substrate 114 to be in the plane of the focus of the particle beam 104. As a result, the strike area 106 is minimized in its spatial extent and thus the spatial resolution of a desired processing of a substrate 114 is maximized. Alternatively, the substrate 114 may be located out of the plane of the focus. As a result, the thermal power density can be reduced.

By measuring the surface properties of the substrate 114, for example the surface unevenness, the two-dimensional removal rate of the particle beam 104 on the substrate 114 can be determined by means of, for example, interferometric methods and a comparison with the previously determined data of the substrate 114. This two-dimensional removal rate may correspond to the Gaussian two-dimensional removal rate.

Subsequently, the substrate 114 can be applied to the substrate holder in the process chamber 122, and the process chamber 122 can be evacuated to a suitable process pressure by means of a vacuum system. As described above, the particle beam source 102 can then be put into operation with a stable particle beam 104.

Subsequently, a determination of the two-dimensional distribution density function of the particle beam can be performed. This can result in a two-dimensional distribution density function in the corresponding parameters being adapted such that a two-dimensional correlated distribution density function is generated which models the two-dimensional removal rate of the strike area of the beam (the so-called base point) with sufficient accuracy. The corresponding accuracy depends on the desired result for a processed substrate 114.

Subsequently, a calculation can take place by means of the determination device 122. This calculation may use the two-dimensional correlated distribution density function to determine a motion profile for the particle beam 104 relative to the substrate 114. Alternatively, the two-dimensional removal rate of the base point may be used to create this motion profile and store it in a memory of the source controller 112, for example.

This motion profile may include positions, respective residence times, duty cycles, and pulse shapes of the strike area 106 of the particle beam 104 on the substrate. Alternatively, the motion profile may include data for velocities, with the velocities describing the velocity of movement of the particle beam 104 relative to the surface of the substrate 114.

The motion profile may have one, two or more scan passes. In a scan pass, the particle beam source is passed over each area of the surfaces. In this case, a particle beam that is pulsed, unpulsed or not (for example, by blocking the beam with a shield) can strike the surface of the substrate.

The detector 122 may be electrically connected to the source controller 112 and/or the holder (not shown) so that the motion profile may be performed. Subsequently, by means of the source control 112 and the holder, the strike area 106 of the particle beam 104 can be guided over the surface of the substrate 114 in accordance with the movement profile, which corresponds to a processing of the surface of the substrate 114. The processed substrate 114 may then be removed from the process chamber 122.

A method implemented in the determination device 122 can, for example, calculate the movement profile such that the surface of the substrate has a desired pattern or a surface that is as flat as possible after the processing.

In order to produce a locally different removal, or a locally different deposition, the substrate and/or the particle beam is moved with mechanical positioning systems and/or the particle beam is pulsed, for example with different duty cycles.

Due to the limited mechanical dynamics of mechanical systems, the minimum residence time per surface segment is typically at least a few tenths of a millisecond.

By using a pulsed particle beam, the time-averaged beam intensity in a surface segment can be reduced. As a result, the minimum local residence time can be reduced.

The motion profile is part of a method for processing a surface of a substrate 114 by means of the particle beam 104 in various exemplary embodiments.

The method comprises the irradiation of the surface of the substrate 104 with the particle beam 104. Upon irradiation, the surface of the substrate is processed with the particle beam in a first area of the surface of the substrate, which strike the surface of the substrate in an unpulsed manner. In a second area of the surface of the substrate, the surface of the substrate is irradiated upon irradiation with the particle beam pulsed on the surface of the substrate.

Alternatively or additionally, when irradiated in a first area of the surface of the substrate, the surface of the substrate is processed with the particle beam, which, pulsed with a first duty cycle, strikes the surface of the substrate. In a second area of the surface of the substrate, the surface of the substrate is processed with the particle beam pulsed with a second duty cycle, which strikes the surface of the substrate. The second duty cycle is different from the first duty cycle.

The pulsed irradiation takes place, for example, after an unpulsed irradiation of the surface of the substrate and/or of an area of the surface of the substrate. Alternatively, the unpulsed irradiation of the surface of the substrate and/or a portion of the surface of the substrate takes place after the pulsed irradiation.

The particle beam is, for example, a beam of neutral particles, a cluster beam, a cluster ion beam, an ion beam or an electron beam. The method of processing a surface of a substrate is magnetron sputtering, for example.

When processing the surface with the particle beam, material can be removed from the surface of the substrate and/or material can be deposited on the surface of the substrate.

The first area, i.e. the unpulsed processed area, may be different from the second area, i.e. the pulsed processed area. The non-pulsed processed area can be processed by pulsing in a later process such as another scan.

All components of the device such as current-measuring device, holder or current probe can be adapted to the particular environment. For example, in the case that the device is operated in a vacuum, flow guides, greases and component materials may be adapted.

The method according to various embodiments is described in more detail in connection with FIG. 3.

FIG. 2 shows a block diagram for source control of a device according to various exemplary embodiments. The source controller 112 has one or more ports 202 by means of which the device may be connected to or integrated with a device-external environment such as a security controller or remote monitor.

The source controller 112 may include a processor 204, a computer 204, or other computing device 204 (hereinafter referred to as a process module computer PMC) that receives, evaluates and controls the individual signals of the components and modules of the device.

The PMC 204 may be a freely programmable processor (e.g. a microprocessor or a nanoprocessor) or hard-wired logic, or firmware, or for example an application-specific integrated circuit (ASIC) or field programmable gate array (field programmable gate array), FPGA).

Among other things, an axis system 206 is connected to the PMC 204, which is connected to a particle beam circuit 208 and an accelerator circuit 210 by means of a switch circuit 212 is connected to control the particle beam 104 of the beam source 102 and its beam profile.

The particle beam switching circuit 208 and the accelerator circuit 210 may each have a power supply, which may be technically equal to each other.

The switch circuit 212 may each comprise an electrically switchable switch, for example a power transistor, between the radiation source 102 and the particle beam circuit 208 and/or between the radiation source 102 and the accelerator circuit 210. The switch circuit 212 may be configured such that the electric potential of the particle beam circuit 208 or the accelerator circuit 210 can be electrically connected to the radiation source 102, or alternatively, a ground potential or another electrical potential can be applied to the radiation source 102. This way, the particle beam can be easily pulsed and the position of the pulses on the surface and its energy can be easily adjusted.

FIG. 3 shows a diagram of the method according to various exemplary embodiments.

The motion profile described above may, in various exemplary embodiments, be a method 300 for the processing of a surface 302 of a substrate by means of a particle beam 104.

In the upper part of FIG. 3, a cross-sectional profile of a surface 302 of a substrate to be processed by means of a particle beam 104 is shown. The particle beam is driven or guided over the surface in several passes (scans) S1, S2, S3. Meanwhile, material may be pulsed 310 from the surface of the substrate, i.e. removed by means of particle beam pulses 304 or unpulsed 308, i.e. in a continuous wave mode 306, or the surface may remain unprocessed. For example, if the surface is not processed, the particle beam is switched off or blocked, so that no material is removed from the surface.

The non-processing has a duty cycle of 0.0. The unpulsed processing has a duty cycle of 1.0. The pulsed processing has a duty cycle greater than 0.0 and smaller than 1.0.

Below the cross-sectional profile, the local removal rate 332 for the segments of the surface and the velocity profile 334 and the different scans S1, S2, S3 for the cross-sectional profile are respectively shown. The removal rate 332 can be set at a constant energy density of the particle beam by means of the residence time per position. The residence time can be adjusted for example by means of the feed rate of the particle beam. By local variation of the feed rate and thus the residence time, a modulation of the absorbed dose can be achieved. A change in feed rate, and hence residence time, would be apparent from velocity profile 334 of the particle beam. The particle beam may be guided for example at a lower speed over a first area 336 than over a second area 338.

The sum of the material removed in several scans S1, S2, S3 corresponds approximately to the material shown in the cross-sectional profile above the target plane 330 (described in more detail below), if the surface 302 of the substrate is arranged below a base plane 320 (described in more detail below).

The surface to be processed can be irradiated at maximum speed in segments with a surface substantially below a base plane 320 and at lower speed around the edges (illustrated in the diagram 334 for the respective scans).

The surface of the substrate exposed in the respective scan of the plurality of scans S1, S2, S3 is processed in such a way by the particle beam 104 that the largest possible portion 318 of the material in a segment is removed unpulsed, for example with a device-specific minimum removal time and residence time for one segment each. A remaining remainder 314 is removed in a scan in a pulsed manner by means of the smallest possible duty cycle. The duty cycle can be realized by means of one pulse or by means of a plurality of pulses, which are for example applied symmetrically to the center of a segment in the segment.

By combining the unpulsed processing 308 with the pulsed processing 310, the number of pulses can be reduced or minimized. This way, the error generated by the slopes of the pulses in the processing of the substrate can be reduced compared to a purely pulsed processing.

The error caused by the slopes and the position assignment of the pulses is mapped, for example, by the continuous particle beam profile when switching the striking of the particle beam on the surface on and off.

In comparison to an unpulsed surface processing, i.e. continuous wave processing, an unnecessary or inadequate processing of the surfaces can be avoided or reduced. As a result, the surface can be processed more precisely, and the surface can have a lower roughness or a higher homogeneity or conformity with a given surface quality.

The method comprises, for example, the detection of a surface condition of at least one part of the surface of the substrate. The excess material or the lack of material can be determined for example starting from the surface 302 of the substrate relative to a predetermined target plane 330. The target plane 330 is, for example, a layer thickness to be achieved and/or homogeneity of the surface of the substrate.

In other words, the method may include the determination of a target plane 330 above or below the surface 302 of the substrate. The substrate can be processed at least in an area of the surface of the substrate until it reaches the target plane.

The surface 302 can be divided into several segments. The segments are, for example, flat, two-dimensional areas that are assigned to the surface of the substrate.

The method may further include the definition of a base plane 320 above or below a surface 302 in at least one area of the substrate. The substrate may be pulsed in segments, for example, if the surface of the respective segment meets a predetermined condition with respect to the base plane 320.

In a material-removing method, for example, pulsed processing can take place, if the surface 302 of the respective segment is arranged below the base plane 320. Segments with a surface above the base plane can be processed, for example, in an unpulsed manner, causing a faster material removal to take place.

The base plane 320 may be arranged below and/or above the surface 302 of the segments of the substrate.

In various exemplary embodiments, the base plane 320 is a plane obtained with a rough processing of the surface of the substrate, for example, by (chemical) mechanical polishing.

Alternatively or additionally, the base plane 320 is a plane where, until it is achieved, only the feed rate is used to modify the residence time.

For the individual segments, a number of pulsed processes 310 and unpulsed processes 308 may be determined to get from the surface 302 to the target plane prior to the start the irradiation of the particle beam 104.

The determination of the number of pulsed processes 308 may include, for example, the determination of the pulse widths, pulse amplitudes, pulse shapes, and/or pulse distribution.

The method includes for example the determination of the duty cycle for each area of the surface to be processed. By controlling the duty cycle, the power and current density fluctuations of the beam source can still be compensated within a designated error range, which may occur, for example, due to thermal drifting. For this purpose, the time-averaged source emission current can be used as a measured variable and the duty cycle adjusted so that the source emission current and thus the time-averaged ion current density is kept constant while maintaining the other process parameters.

The particle beam may strike the surface of the substrate in a pulsed manner for example such that the pulses are arranged symmetrically with respect to the center of the area processed in a pulsed manner, i.e. the segment. The particle beam has, for example, a Gaussian beam profile. The symmetrically pulsed irradiated segments thus have, for example, a higher homogeneity in relation to a point-symmetrical processing relative to the center of the segment and/or with respect to an asymmetric processing.

The pulsed processing includes multiple pulses 304, for example, which may be located at the edge or between the edge and the center of a segment.

In various embodiments, the method includes further irradiation 312 of the surface of the substrate. Upon further irradiation 312, the particle beam 104 is blocked in a area of the surface of the substrate in which the target plane 330 has been reached, for example by means of a shield or by means of a switch circuit of the source controller 112. By means of such blocking, it is possible to prevent the surface in this area from being processed by the particle beam. In other words, during further processing, the beam source, for example the ion source, can be switched off completely, i.e. the duty cycle is 0.0. In the case for example, where the ion beam is guided from one position to another position of the substrate, this is done without coating or etching the surface segments.

Through the simultaneous use of an adapted residence time and pulse duration as a process parameter, the speed of the substrate or ion beam can be made more uniform and the overall process is more moderate, resulting in a longer life of the components of the positioning system.

1. A method for processing a surface of a substrate using a particle beam, the method comprising:
irradiating the surface of the substrate with the particle beam,
wherein, in a first area of the surface of the substrate, the surface of the substrate is processed with the particle beam which strikes the surface of the substrate in an unpulsed manner; and
wherein in at least a second area of the surface of the substrate, the surface of the substrate is processed with the particle beam which strikes the surface of the substrate in a pulsed manner.

2. A method for processing a surface of a substrate using a particle beam, the method comprising:
irradiating the surface of the substrate with the particle beam,
wherein, in a first area of the surface of the substrate, the surface of the substrate is processed with the particle beam, which, pulsed with a first duty cycle, strikes the surface of the substrate; and
wherein in at least a second area of the surface of the substrate, the surface of the substrate is processed with the particle beam with a second duty cycle in a pulsed manner, wherein the second duty cycle is different from the first duty cycle.

3. The method according to claim 1, further comprising determining a number of pulsed and unpulsed processes for each surface area to be processed.

4. The method according to claim 3, wherein the determining the number of pulsed processes comprises determining pulse widths, pulse amplitudes, pulse shapes, pulse position, and/or pulse distribution.

5. The method according to claim 1, wherein the particle beam strikes the surface of the substrate in a pulsed manner such that the pulses are symmetrically arranged around the center of the pulsed processed area.

6. The method according to claim 1, further comprising defining a base plane above or below a surface in at least one area of the substrate, wherein the substrate is pulsed in the area when the surface of the area has a predetermined relationship to the base plane, and the area is otherwise unpulsed or not processed.

7. The method according to claim 2, further comprising determining the first duty cycle and the second duty cycle for each area of the surface to be processed.

8. The method according to claim 1, wherein the pulsed irradiation in an area of the surface occurs after the unpulsed irradiation in the same area of the surface.

9. The method according to claim 1, wherein the unpulsed irradiation of an area of the surface occurs after the pulsed irradiation of the same area of the surface.

10. The method according to claim 1, wherein the particle beam is a neutral particle beam, a beam of a particle bundle, an ion beam or an electron beam.

11. The method according to claim 1, wherein, when processing the surface with the particle beam, material is removed from the surface or a portion of the surface of the substrate.

12. The method according to claim 1, wherein, when processing the surface with the particle beam, material is deposited on the surface or a portion of the surface of the substrate.

13. The method according to claim 1, wherein the first area is different from the second area.

14. The method according to claim 1, further comprising detecting a surface condition of at least a portion of the surface of the substrate.

15. The method according to claim 1, further comprising determining a target plane above or below the surface of the substrate, wherein the substrate is processed in an area of the surface of the substrate until reaching the target plane.

16. The method according to claim 15, further comprising further irradiating the surface of the substrate, wherein in an area of the surface of the substrate in which the target plane has been reached, the particle beam is blocked so that the surface in this area is not processed by the particle beam.

17. The method according to claim 1, further comprising conducting at least one other further irradiation, wherein the first area of the surface of the substrate of the unpulsed irradiation is processed during the at least one other further irradiation with the particle beam which is pulsed onto the surface of the substrate.

18. A device for processing a surface of a substrate using a particle beam, the device comprising:
a particle beam source configured to process the surface of the substrate with a particle beam; and
a source controller configured to control the particle beam, wherein the source controller is configured to irradiate the surface of the substrate with the particle beam,
wherein, in a first area of the surface of the substrate, the surface of the substrate is processed with the particle beam which strikes the surface of the substrate in an unpulsed manner; and
wherein, in a second area of the surface of the substrate, the surface of the substrate is processed with the particle beam which is pulsed onto the surface of the substrate.

19. A device for processing a surface of a substrate using a particle beam, the device comprising:
a particle beam source configured to process a surface of a substrate with a particle beam; and
a source controller configured to control the particle beam, wherein the source controller is configured to irradiate the surface of the substrate with the particle beam,
wherein, in a first area of the surface of the substrate, the surface of the substrate is processed with the particle beam, which, pulsed with a first duty cycle, strikes the surface of the substrate; and
wherein, in a second area of the surface of the substrate, the surface of the substrate is processed with the particle beam, pulsed with a second duty cycle striking the surface of the substrate, wherein the second duty cycle is different from the first duty cycle.

20. A device according to claim 18, further comprising a process chamber, wherein at least a portion of particle beam source and the substrate are arranged in the process chamber.
